(19) United States
(12) Patent Application Publication
(10) Pub. No.: US 2024/0414978 A1
(43) Pub. Date: Dec. 12, 2024

(54) DISPLAY DEVICE AND METHOD OF MANUFACTURING THE SAME

(71) Applicant: Samsung Display Co., Ltd., Yongin-si, Gyeonggi-do (KR)

(72) Inventors: Junghwa Park, Yongin-si (KR); Changho Lee, Yongin-si (KR); Mihyang Sheen, Yongin-si (KR); Nari Ahn, Yongin-si (KR); Jaehan Lee, Yongin-si (KR)

(21) Appl. No.: 18/417,894

(22) Filed: Jan. 19, 2024

(30) Foreign Application Priority Data
Feb. 24, 2023 (KR) 10-2023-0025285

(51) Int. Cl. H10K 59/80; H10K 59/12

(52) U.S. Cl. CPC H10K 59/80518; H10K 59/1201

(57) ABSTRACT

A display device includes a substrate, a pixel circuit layer above the substrate, and including at least one thin film transistor, and a pixel electrode above the pixel circuit layer, and electrically connected to the thin film transistor, wherein the pixel electrode includes a reflective layer, a conductive layer above the reflective layer, and an oxide layer above the conductive layer, and wherein a ratio of a thickness of the conductive layer and a thickness of the oxide layer is about 1.51 to about 2.331.

### CROSS-REFERENCE TO RELATED APPLICATION

This application claims priority to, and the benefit of, Korean Patent Application No. 10-2023-0025285, filed on Feb. 24, 2023, in the Korean Intellectual Property Office, the disclosure of which is incorporated by reference herein in its entirety.

### BACKGROUND

### 1. Field

One or more embodiments relate to a display device, and to a method of manufacturing the same.

### 2. Description of the Related Art

Display devices provide visual information, such as images or videos, to users. With the development of various electronic devices, such as computers, large TVs, and the like, various types of display devices to be employed therein have been developed recently, and mobility-based electronic devices are widely used. For example, not only compact electronic devices, such as mobile phones, but also tablet personal computers (PCs) are widely used as mobile electronic devices.

A display device includes a display area and a non-display area, and a plurality of light-emitting elements are arranged in the display area. The display device may provide an image through light emitted by the light-emitting elements. The light-emitting elements may include a pixel electrode and a counter electrode.

### SUMMARY

One or more embodiments include a display device with improved reliability, and a method of manufacturing the same. However, such an aspect is merely an example, and the scope of the disclosure is not limited thereby.

1 Additional aspects will be set forth in part in the description that follows and, in part, will be apparent from the description, or may be learned by practice of the presented embodiments of the disclosure.

According to one or more embodiments, a display device includes a substrate, a pixel circuit layer above the substrate, and including at least one thin film transistor, and a pixel electrode above the pixel circuit layer, and electrically connected to the thin film transistor, wherein the pixel electrode includes a reflective layer, a conductive layer above the reflective layer, and an oxide layer above the conductive layer, and wherein a ratio of a thickness of the conductive layer and a thickness of the oxide layer is about 1.51 to about 2.331.

The thickness of the conductive layer may be greater than or equal to about 20 Å and less than or equal to about 100 Å.

The thickness of the oxide layer may be less than or equal to about 10 Å.

A thickness of the reflective layer may be greater than or equal to about 800 Å and less than or equal to about 1,200 Å.

The conductive layer may include titanium nitride (TiN).

The oxide layer may include titanium oxynitride (TION) or titanium oxide (TiOₓ).

The oxide layer may include a first oxide layer including titanium oxynitride (TION), and a second oxide layer above the first oxide layer, and including titanium oxide (TiOₓ).

The reflective layer may include an aluminum-copper alloy (Al—Cu alloy).

An atomic ratio of Cu in the aluminum-copper alloy (Al—Cu alloy) may be greater than or equal to about 0.01 at % and less than or equal to about 0.1 at %.

The substrate may include a semiconductor substrate.

According to one or more embodiments, a method of manufacturing a display device includes forming, on a substrate, a pixel circuit layer including at least one thin film transistor, forming, on the pixel circuit layer, a reflective layer of a pixel electrode electrically connected to the pixel circuit layer, forming a conductive layer of the pixel electrode on the reflective layer of the pixel electrode, and forming an oxide layer on the conductive layer of the pixel electrode, by oxidizing at least a portion of a material included in the conductive layer, wherein a ratio of a thickness of the conductive layer and a thickness of the oxide layer is about 1.51 to about 2.331.

The forming the reflective layer and forming the conductive layer may include forming a reflective-layer-forming material on the pixel circuit layer, forming a conductive-layer-forming material on the reflective-layer-forming material, forming photoresist on at least a portion of the conductive-layer-forming material, forming the reflective layer and the conductive layer by etching at least portions of the reflective-layer-forming material and the conductive-layer-forming material on which the photoresist is not arranged, and removing the photoresist.

The method may further include skipping ashing a surface of the conductive layer with oxygen (O₂) after the forming the conductive layer.

The thickness of the conductive layer may be greater than or equal to about 20 Å and less than or equal to about 100 Å.

The thickness of the oxide layer may be less than or equal to about 10 Å.

A thickness of the reflective layer may be greater than or equal to about 800 Å and less than or equal to about 1,200 Å.

The conductive layer may include titanium nitride (TIN), wherein the oxide layer includes titanium oxynitride (TION) or titanium oxide (TiOₓ).

The oxide layer may include a first oxide layer including titanium oxynitride (TION), and a second oxide layer above the first oxide layer, and including titanium oxide (TiOₓ).

The reflective layer may include an aluminum-copper alloy (Al—Cu alloy), wherein, in the aluminum-copper alloy (Al—Cu alloy), an atomic ratio of Cu is greater than or equal to about 0.01 at % and less than or equal to about 0.1 at %.

The substrate may include a semiconductor substrate.

### BRIEF DESCRIPTION OF THE DRAWINGS

The above and other aspects of certain embodiments of the disclosure will be more apparent from the following description taken in conjunction with the accompanying drawings, in which:

FIG. 1 is a schematic perspective view of a display device according to one or more embodiments;

FIG. 2 is a schematic equivalent circuit diagram of one pixel in the display device of FIG. 1;

FIG. 3 is a schematic cross-sectional view of a display device according to one or more embodiments;

FIG. 4 is a schematic enlarged view of a region A of FIG. 3 according to one or more embodiments;

FIG. 5 is a photo of a pixel electrode according to one or more embodiments, and a schematic view of a component analysis result graph of a pixel electrode according to one or more embodiments;

FIG. 6 is a graph showing a current density according to a voltage of a pixel electrode when an oxygen-ashing (O₂-ashing) process, which is one of processes of a display device according to one or more embodiments, is performed, and when the O₂-ashing process is not performed; and

FIGS. 7 to 12 are schematic cross-sectional views showing a method of manufacturing a pixel electrode of a display device, according to one or more embodiments.

### DETAILED DESCRIPTION

Aspects of some embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may have various modifications and may be embodied in different forms, and should not be construed as being limited to only the illustrated embodiments herein. Further, each of the features of the various embodiments of the present disclosure may be combined or combined with each other, in part or in whole, and technically various interlocking and driving are possible. Each embodiment may be implemented independently of each other or may be implemented together in an association. The described embodiments are provided as examples so that this disclosure will be thorough and complete, and will fully convey the aspects of the present disclosure to those skilled in the art, and it should be understood that the present disclosure covers all the modifications, equivalents, and replacements within the idea and technical scope of the present disclosure. Accordingly, processes, elements, and techniques that are not necessary to those having ordinary skill in the art for a complete understanding of the aspects of the present disclosure may not be described.

Unless otherwise noted, like reference numerals, characters, or combinations thereof denote like elements throughout the attached drawings and the written description, and thus, descriptions thereof will not be repeated. Further, parts that are not related to, or that are irrelevant to, the description of the embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Thus, the regions illustrated in the drawings are schematic in nature and their shapes are not intended to illustrate the actual shape of a region of a device and are not intended to be limiting. Additionally, as those skilled in the art would realize, the described embodiments may be modified in various ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component. In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expression such as “at least one of A and B” and “at least one of A or B” may include A, B, or A and B. As used herein, “or” generally means “and/or,” and the term “and/or” includes any and all combinations of one or more of the associated listed items. For example, the expression such as “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112 (a) and 35 U.S.C. § 132 (a).

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

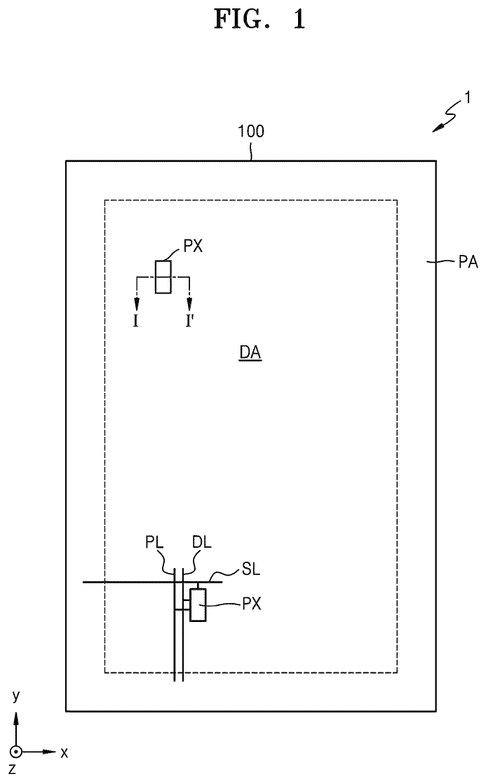

FIG. 1 is a schematic perspective view of a display device 1 according to one or more embodiments.

Referring to FIG. 1, the display device 1 according to one or more embodiments may include various devices, such as smartphones, tablets, laptops, televisions, billboards, or the like. The display device 1 according to one or more embodiments includes thin film transistors, capacitors, and the like, and thus, the thin film transistors, capacitors, and the like may be implemented by conductive layers and insulating layers.

The display device 1 may include a display area DA, and a peripheral area PA arranged outside the display area DA. FIG. 1 illustrates that the display area DA has a rectangular shape. However, the disclosure is not limited thereto. The display area DA may have various shapes, for example, circular, oval, polygonal, and the like.

The display area DA is a portion for displaying an image, and a plurality of pixels PX may be located therein. Each pixel PX may include a display element, such as an organic light-emitting diode. Each pixel PX may emit, for example, red, green, or blue light. The pixel PX may be connected to a pixel circuit including a thin film transistor TFT, a storage capacitor, and the like. The pixel circuit may be connected to a scan line SL for transmitting a scan signal, a data line DL for transmitting a data signal, the data line DL crossing the scan line SL, a driving voltage line PL for supplying a driving voltage, and the like. The scan line SL may extend in an x direction (hereinafter, referred to as the second direction), and the data line DL and the driving voltage line PL may extend in a y direction (hereinafter, referred to as the first direction).

The pixel PX may emit light having a luminance corresponding to an electrical signal from the electrically connected pixel circuit. The display area DA may display an image through the light emitted from the pixel PX. For reference, the pixel PX may be defined as an emission area where light of any one color of red, green, or blue is emitted, as described above.

The peripheral area PA, which is an area in which the pixel PX is not arranged, may be an area where no image is displayed. A power supply wire for driving of the pixel PX, and the like may be located in the peripheral area PA. Furthermore, pads are arranged in the peripheral area PA, and a printed circuit board including a drive circuit portion, or an integrated circuit (IC) device, such as a driver IC, may be arranged to be electrically connected to the pads.

For reference, as the display device 1 includes a substrate 100, it may be said that the substrate 100 includes the display area DA and the peripheral area PA. The substrate 100 is described below in detail.

Furthermore, a plurality of transistors may be arranged in the display area DA. In each of the transistors, depending on the type (N-type or P-type) of transistor and/or operation conditions, a first terminal may be a source electrode or a drain electrode, and a second terminal may be an electrode that is different from the first terminal. For example, when the first terminal is a source electrode, the second terminal may be a drain electrode.

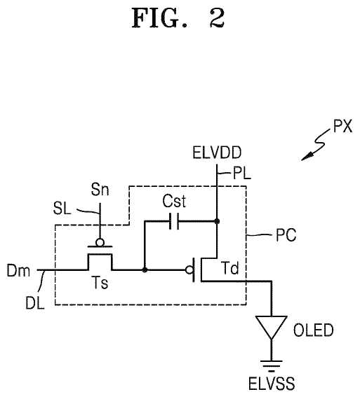

The transistors may include a driving transistor, a data write transistor, a compensation transistor, an initialization transistor, an emission control transistor, and the like. The driving transistor Td may be connected between the driving voltage line PL and an organic light-emitting diode OLED (see FIG. 2), and the data write transistor Ts may be connected between the data line DL and the driving transistor Td, and may perform a switching operation of transmitting a data signal Dm received through the data line DL.

The compensation transistor Ts may be turned on in response to a scan signal Sn received through the scan line SL to connect the driving transistor Td to the organic light-emitting diode OLED, thereby compensating for a threshold voltage of the driving transistor Td.

The initialization transistor may be turned on in response to the scan signal Sn received through the scan line SL to transmit an initialization voltage to a gate electrode of the driving transistor Td, thereby initializing the gate electrode of the driving transistor Td. The scan line connected to the initialization transistor may be a separate scan line that is different from the scan line SL connected to the compensation transistor Ts.

The emission control transistor may be turned on in response to an emission control signal received through an emission control line, and as a result, a driving current may flow in the organic light-emitting diode OLED.

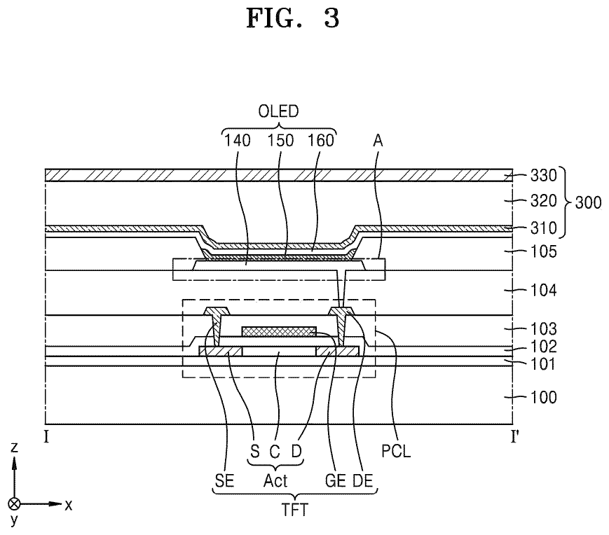

The organic light-emitting diode OLED may include a pixel electrode (anode) and a counter electrode (cathode) 160 (see FIG. 3), and the counter electrode 160 may receive a second power voltage ELVSS (see FIG. 2). The organic light-emitting diode OLED may emit light by receiving the driving current from the driving transistor Td, thereby displaying an image.

In the following description, although an organic light-emitting display device is described as an example of the display device 1 according to one or more embodiments, the display device 1 of one or more embodiments is not limited thereto. In one or more other embodiments, the display device 1 of one or more embodiments may be a display device, such as an inorganic light-emitting display device or an inorganic electroluminescent (EL) display device, or a quantum-dot light-emitting display device. For example, a light-emitting layer of a display element included in the display device 1 may include an organic material or an inorganic material. Furthermore, the display device 1 may include the light-emitting layer, and quantum dots located on a path of the light emitted from the light-emitting layer.

FIG. 2 is a schematic equivalent circuit diagram of one pixel included in the display device 1 of FIG. 1.

Referring to FIG. 2, each pixel PX includes a pixel circuit PC connected to the scan line SL and the data line DL and the organic light-emitting diode OLED connected to the pixel circuit PC. The pixel circuit PC includes a driving thin film transistor Td, a switching thin film transistor Ts, and a storage capacitor Cst. The switching thin film transistor Ts is connected to the scan line SL and the data line DL, and in response to a scan signal Sn input through the scan line SL, transmits a data signal Dm input through the data line DL to the driving thin film transistor Td.

The storage capacitor Cst is connected to the switching thin film transistor Ts and the driving voltage line PL, and stores a voltage corresponding to a difference between a voltage received from the switching thin film transistor Ts and a first power voltage ELVDD supplied through the driving voltage line PL. The second power voltage ELVSS may be a driving voltage having a relatively low level compared with the first power voltage ELVDD. The level of a driving voltage applied to each pixel PX may be a difference between the level of the first power voltage ELVDD and the level of a second power voltage ELVSS.

The driving thin film transistor Td is connected to the driving voltage line PL and to the storage capacitor Cst, and may control the driving current flowing in the organic light-emitting diode OLED from the driving voltage line PL corresponding to the value of a voltage stored in the storage capacitor Cst. The organic light-emitting diode OLED may emit light having a luminance corresponding to the driving current (e.g., the magnitude of the driving current).

FIG. 3 is a schematic cross-sectional view of the display device 1 according to one or more embodiments. In detail, FIG. 3 is a schematic cross-sectional view of the display device 1 taken along the line I-I′ of the display device 1 of FIG. 1.

Referring to FIG. 3, the display device 1 may include the substrate 100, a pixel circuit layer PCL, the organic light-emitting diode OLED, and an encapsulation layer 300.

To realize an ultra-high resolution, the substrate 100 may include a semiconductor material, for example, a Group IV semiconductor, a Group III-V compound semiconductor, or a Group II-VI compound semiconductor. The substrate 100 may include a silicon layer. In other words, the substrate 100 may be a semiconductor substrate including a semiconductor material. In one or more embodiments, the substrate 100 may be a C-MOS substrate. As such, an OLED display device using the substrate 100 including a semiconductor material may be referred to as an OLED on silicon (OLEDoS). OLEDoS may be mainly used for extended reality (XR) and the like, and may realize an ultra-high resolution of 8K or more within a small area of about 1 to about 2 inches. When a semiconductor substrate is in use, a fine control of pixels arranged at an ultra-high resolution may be possible. In other words, for a display device having a length of about 2 μm to about 4 μm in the first direction (for example, x direction or −x direction) of one pixel PX (see FIG. 1), the semiconductor substrate may be used. However, the disclosure is not limited thereto.

The type of the substrate 100 may not be limited to the semiconductor substrate. For example, the substrate 100 may include glass, metal, or polymer resin. Furthermore, the substrate 100 may include polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 may be variously modified, for example, the structure 100 may have a multilayer structure including two layers each including polymer resin as described above and a barrier layer arranged between the two layers and including an inorganic material, such as silicon oxide, silicon nitride, silicon oxynitride, and/or the like.

A buffer layer 101 may be located on the substrate 100. The buffer layer 101 may reduce or prevent diffusion of impurity ions, may reduce or prevent infiltration of moisture or external air, and may serve as barrier layer and/or blocking layer for planarizing a surface. The buffer layer 101 may include silicon oxide, silicon nitride, or silicon oxynitride. Furthermore, the buffer layer 101 adjusts a speed for providing heat during a crystallization process for forming a semiconductor layer Act, so that the semiconductor layer Act may be uniformly crystallized. However, the disclosure is not limited thereto. In one or more other embodiments of the disclosure, the buffer layer 101 may be omitted.

The pixel circuit layer PCL may be located on the substrate 100 or the buffer layer 101. The pixel circuit layer PCL may include at least one thin film transistor TFT electrically connected to the organic light-emitting diode OLED, a gate insulating layer 102, and an interlayer insulating layer 103. In one or more embodiments, the thin film transistor TFT may include the semiconductor layer Act, a gate electrode GE, a source electrode SE, and a drain electrode DE.

In one or more embodiments, the semiconductor layer Act may be located on the buffer layer 101. The semiconductor layer Act may include polysilicon, and may include a channel region C not doped with impurities, and a source region S and a drain region D arranged at respective sides of the channel region C and doped with impurities. The impurities may vary according to the type of the thin film transistor TFT, and N-type impurities or P-type impurities are possible.

In one or more embodiments, the gate insulating layer 102 may be located on the semiconductor layer Act. The gate insulating layer 102 may be a configuration to secure insulation between the semiconductor layer Act and the gate electrode GE. The gate insulating layer 102 may include an inorganic material, such as silicon oxide, silicon nitride, silicon oxynitride, and/or the like, and may be provided between the semiconductor layer Act and the gate electrode GE. Furthermore, the gate insulating layer 102 has a shape corresponding to the entire surface of the substrate 100, and may have a structure in which contact holes are formed in a preset portion. As such, an insulating film including an inorganic material may be formed through chemical vapor deposition (CVD) or atomic layer deposition (ALD). Modified examples thereof are also included in the present disclosure.

The gate electrode GE may be located on the gate insulating layer 102. The gate electrode GE may be located at a position vertically overlapping the semiconductor layer Act, and may include at least one of one or more metals, such as molybdenum (Mo), aluminum (AI), platinum (Pt), palladium (Pd), silver (Ag), magnesium (Mg), gold (Au), nickel (Ni), neodymium (Nd), iridium (Ir), chromium (Cr), lithium (Li), calcium (Ca), titanium (Ti), tungsten (W), or copper (Cu).

The interlayer insulating layer 103 may be located on the gate electrode GE. The interlayer insulating layer 103 may cover the gate electrode GE. The interlayer insulating layer 103 may include an inorganic material. For example, the interlayer insulating layer 103 may be metal oxide or metal nitride, and in detail, the inorganic material may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZrO₂), and/or the like. The interlayer insulating layer 103, in some embodiments, may have a dual structure of SiOₓ/SiN_{y} or SiNₓ/SiO_{y}.

The source electrode SE and the drain electrode DE may be located on the interlayer insulating layer 103. The source electrode SE and the drain electrode DE may be respectively electrically connected to the source region S and the drain region D of the semiconductor layer Act through a respective through-hole included in, or defined by, the interlayer insulating layer 103. The source electrode SE and the drain electrode DE may include one or more metals selected from among Al, Pt, Pd, Ag, Mg, Au, Ni, Nd, Ir, Cr, Ii, Ca, Mo, Ti, W, or Cu. For example, the source electrode SE and the drain electrode DE may include a Ti layer, an Al layer, and/or a Cu layer.

As such, the semiconductor layer Act, the gate electrode GE, the source electrode SE, and the drain electrode DE may form at least one of the thin film transistors described above in FIG. 2. According to the pattern of a preset shape, the semiconductor layer Act, the gate electrode GE, the source electrode SE, and the drain electrode DE may form at least one thin film transistor among the thin film transistors described above in FIG. 2.

An organic insulating layer 104 may be located on the source electrode SE and the drain electrode DE. The organic insulating layer 104 covers the tops of the source electrode SE and the drain electrode DE, has an approximately flat upper surface, and may be an organic insulating layer serving as a planarized film. The organic insulating layer 104 may include an organic material, for example, acryl, benzocyclobutene (BCB), hexamethyldisiloxane (HMDSO), or the like. The organic insulating layer 104 may be deformable in various ways, for example, in a single layer or a multilayer, and the like.

Furthermore, in one or more embodiments, additional electrodes and additional insulating layers may be provided between a pixel electrode 140 and the source electrode SE and the drain electrode DE, and may be applicable in various embodiments. The additional electrodes may include the same material as, and may have the same layer structure as, those of the source electrode SE and the drain electrode DE described above. The additional insulating layers may include the same material as, and may have the same layer structure as, that of the organic insulating layer 104 described above.

In one or more embodiments, the organic light-emitting diode OLED electrically connected to the pixel circuit layer PCL may be located on the pixel circuit layer PCL. The organic light-emitting diode OLED may include the pixel electrode 140, a light-emitting layer 150, and the counter electrode 160.

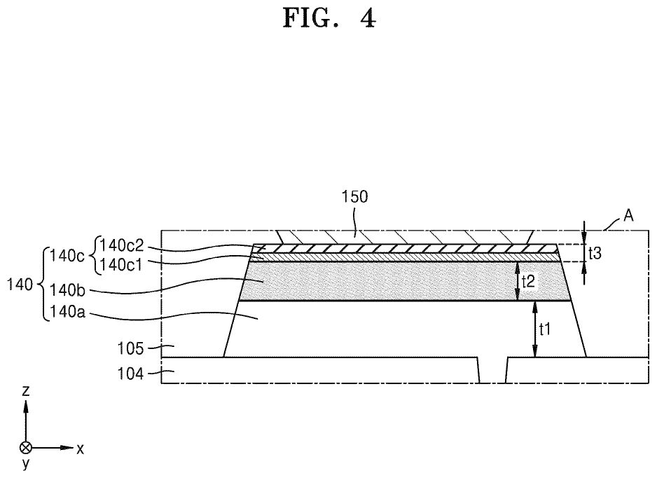

The pixel electrode 140 may be located on the pixel circuit layer PCL. The pixel electrode 140 may be located on the organic insulating layer 104. The pixel electrode 140 may be connected to a source electrode or a drain electrode through a contact hole formed in the insulating layer 104. The structure of the pixel electrode 140 is described below in detail with reference to FIG. 4.

A pixel-defining layer 105, in which an opening for exposing at least a portion of the pixel electrode 140 is defined, may be located on the pixel electrode 140. An emission area of the light emitted from the organic light-emitting diode OLED may be defined by the opening defined in the pixel-defining layer 105. For example, the width of the opening may correspond to the width of the emission area.

The pixel-defining layer 105 may include an organic insulating material. Alternatively, the pixel-defining layer 105 may include an inorganic insulating material, such as silicon nitride, silicon oxynitride, or silicon oxide. Alternatively, the pixel-defining layer 105 may include an organic insulating material and an inorganic insulating material. In one or more embodiments, the pixel-defining layer 105 may include a light-blocking material. The light-blocking material may include carbon black, carbon nanotube, resin or paste including black dye, metal particles, for example, nickel, aluminum, molybdenum, and/or an alloy thereof, metal oxide particles, for example, chromium oxide, or metal nitride particles, for example, chromium nitride, and/or the like. When the pixel-defining layer 105 includes a light-blocking material, external light reflection by metal structures arranged below the pixel-defining layer 105 may be reduced.

The light-emitting layer 150 may be arranged in the opening of the pixel-defining layer 105. The light-emitting layer 150 may include a polymer or low molecular weight organic material for emitting light of a corresponding color.

In one or more embodiments, a first functional layer and a second functional layer may be located respectively below and above the light-emitting layer 150. The first functional layer and the second functional layer may be consecutively arranged on the substrate 100. The first functional layer may be arranged between the pixel electrode 140 and the light-emitting layer 150, and the second functional layer may be arranged between the light-emitting layer 150 and the counter electrode 160. However, at least one of the first functional layer or the second functional layer may be omitted. In the following description, a case in which the first function layer and the second functional layer are respectively arranged is mainly described in detail.

The first functional layer may include a hole transport layer (HTL) and/or a hole injection layer (HIL). The second functional layer may include an electron transport layer (ETL) and/or an electron injection layer (EIL). The first functional layer and/or the second functional layer, like the counter electrode 160 described below, each may be a common layer formed to entirely cover the substrate 100.

In one or more embodiments, the counter electrode 160 may be located on the light-emitting layer 150. The counter electrode 160 may include a conductive material having a low work function. For example, the counter electrode 160 may include a (semi-) transparent layer including Ag, Mg, Al, Pt, Pd, Au, Ni, Nd, Ir, Cr, Ii, Ca, or an alloy thereof, and/or the like. Alternatively, the counter electrode 160 may further include a layer, such as ITO, IZO, ZnO, or In₂O₃, on the (semi-) transparent layer including the material described above.

In one or more embodiments, the encapsulation layer 300 may be located on the organic light-emitting diode (OLED). The encapsulation layer 300 may cover the organic light-emitting diode OLED. The encapsulation layer 300 may be located on the counter electrode 160. In one or more embodiments, the encapsulation layer 300 may include at least one inorganic film layer, and may also include at least one organic film layer. FIG. 3 illustrates that the encapsulation layer 300 includes a first inorganic film layer 310, an organic film layer 320, and a second inorganic film layer 330, which are sequentially stacked.

The first inorganic film layer 310 and the second inorganic film layer 330 may each include one or more inorganic materials of aluminum oxide, titanium oxide, tantalum oxide, hafnium oxide, zinc oxide, silicon oxide, silicon nitride, or silicon oxynitride. The first inorganic film layer 310 and the second inorganic film layer 330 may each be a single layer or a multilayer including the material described above. The organic film layer 320 may include a polymer-based material. The polymer-based material may include acrylic resin, epoxy-based resin, polyimide, polyethylene, and the like. In one or more embodiments, the organic film layer 320 may include acrylate.

FIG. 4 is a schematic enlarged view of a region A of FIG. 3 according to one or more embodiments. In detail, FIG. 4 is a schematic enlarged view of a pixel electrode according to one or more embodiments.

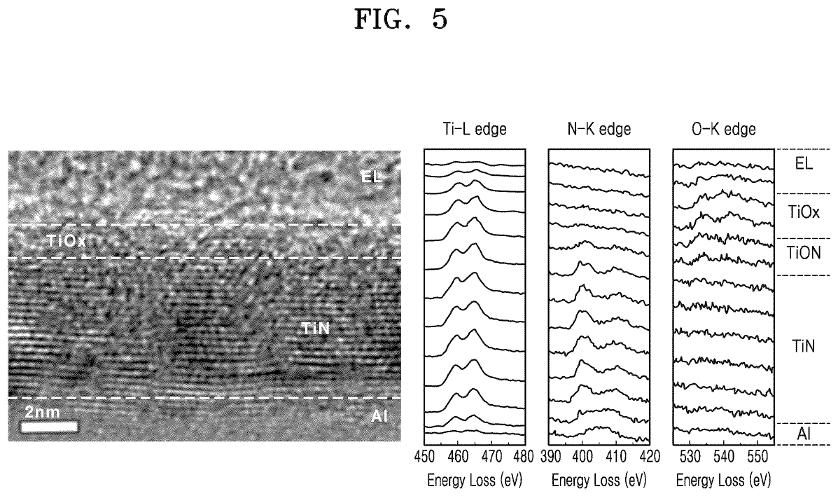

FIG. 5 is a photo of a pixel electrode according to one or more embodiments, and a schematic view of a component analysis result graph of a pixel electrode according to one or more embodiments.

Referring to FIGS. 4 and 5, the pixel electrode 140 may include a reflective layer 140a, a conductive layer 140b, and an oxide layer 140c. The conductive layer 140b may be located on the reflective layer 140a, and the oxide layer 140c may be located on the conductive layer 140b. In detail, the conductive layer 140b may be arranged in contact with the upper surface of the reflective layer 140a, and the oxide layer 140c may be arranged in contact with the upper surface of the conductive layer 140b.

In one or more embodiments, the reflective layer 140a of the pixel electrode 140 may include an aluminum-copper alloy (Al—Cu alloy). In the Al—Cu alloy of the reflective layer 140a, an atomic ratio of Cu may have a range of greater than or equal to about 0.01 at % and less than or equal to about 0.1 at %. When the reflective layer 140a of the pixel electrode 140 includes Al 100%, due to the properties of Al, the reflective layer 140a of the pixel electrode 140 may not be sufficiently flat, and may affect the reflectivity of the display device 1. An oxide film may be formed to be relatively thick on the reflective layer 140a, as compared with a case in which the reflective layer 140a is formed of the Al—Cu alloy.

A thickness t1 of the reflective layer 140a may be greater than or equal to about 800 Å and less than or equal to about 1200 Å. The thickness t1 of the reflective layer 140a may refer to a thickness in a direction perpendicular to the substrate 100, that is, a thickness in a third direction, for example, a z direction or a −z direction. When the thickness t1 of the reflective layer 140a is less than about 800 Å, the reflectivity of the display device 1 may not be sufficiently secured. When the thickness t1 of the reflective layer 140a exceeds about 1200 Å, the resistance of the pixel electrode 140 increases so that a current may not flow well, and thus, the luminance and the like of the display device 1 may be negatively affected.

In one or more embodiments, the conductive layer 140b of the pixel electrode 140 may include titanium nitride (TiN). According to the related art, the pixel electrode 140 of the display device 1 may include indium tin oxide (ITO). In the display device 1 according to one or more embodiments, to realize a high resolution in the pixel PX of FIG. 1 having a size of about 2 μm to about 4 μm, a semiconductor substrate may be used. For example, a C-MOS substrate may be used as the semiconductor substrate. When a semiconductor substrate is used as the substrate 100, there may be a limitation in selecting the material of the pixel electrode 140 in a semiconductor process. In the semiconductor process, a material, such as ITO may be omitted. Due to the absence of an ITO process used in a process of the existing display device, TiN use in the semiconductor process may be used as a material for the pixel electrode 140.

A thickness t2 of the conductive layer 140b of the pixel electrode 140 may be greater than or equal to about 20 Å and less than or equal to about 100 Å. When the thickness t2 of the conductive layer 140b of the pixel electrode 140 is less than about 20 Å, a composition ratio of elements of TiN may become non-uniform. Furthermore, as the work function of TiN included in the conductive layer 140b is changed, the hole injection characteristics of the pixel electrode 140 may be deteriorated. When the thickness t2 of the conductive layer 140b of the pixel electrode 140 exceeds about 100 Å, the reflectivity of the display device 1 deteriorates so that the display device 1 may be negatively affected.

In one or more embodiments, the oxide layer 140c of the pixel electrode 140 may include titanium oxynitride (TION) or titanium oxide (TiOₓ). The oxide layer 140c of the pixel electrode 140 may include a first oxide layer 140c1 and a second oxide layer 140c2. The second oxide layer 140c2 may be located on the first oxide layer 140c1. The first oxide layer 140c1 may include TiON, and the second oxide layer 140c2 may include TiOₓ. The oxide layer 140c of the pixel electrode 140 may be formed by oxidizing the TiN that is a material included in the conductive layer 140b of the pixel electrode 140 through an oxygen-ashing (O₂-ashing) process or a plasma process, after the conductive layer 140b of the pixel electrode 140 is formed. The TiON or TiOₓ included in the oxide layer 140c of the pixel electrode 140 may be a material formed by oxidizing the TiN included in the conductive layer 140b of the pixel electrode 140.

According to the related art, to secure the hole injection characteristics of a pixel electrode of a display device, ITO is used as a material for the pixel electrode. For the display device 1 according to one or more embodiments, in which the size of a pixel is several micro meters, and to realize a high resolution, a semiconductor substrate may be used as the substrate 100. When the semiconductor substrate is used instead of ITO used in the related art, TiN may be used as a material for a pixel electrode of a display device in the semiconductor process. The pixel electrode 140 may include TIN. When the pixel electrode 140 includes TiN through a subsequent process, for example, though an O₂-ashing process or a plasma process, TIN is oxidized so that TiON or TiOₓ is generated. Additionally, due to defects in the crystal phase of TiN, the hole injection characteristics of the pixel electrode 140 may be deteriorated. When the hole injection characteristics of the pixel electrode 140 are deteriorated, compared with a case in which the existing pixel electrode includes ITO, current may not flow well, and the luminance and the like of the display device 1 may be negatively affected.

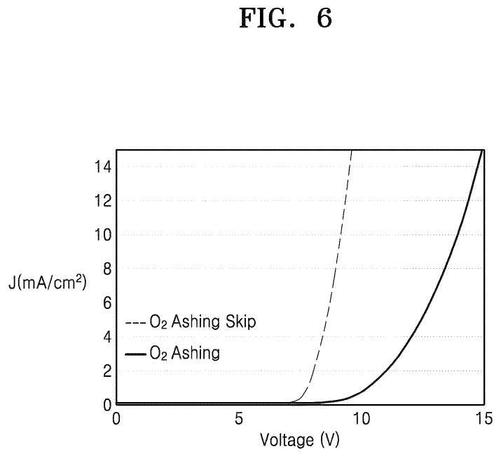

FIG. 6 is a graph showing a current density according to a voltage of a pixel electrode when an oxygen-ashing (O₂-ashing) process that is one of processes of a display device according to one or more embodiments is performed, and when the O₂-ashing process is not performed.

As the conductive layer 140b of the pixel electrode 140 includes TIN, to secure the hole injection characteristics of the pixel electrode 140, the oxidization of TiN included in the conductive layer 140b may be suitably restricted. To restrict oxidization of the conductive layer 140b of the pixel electrode 140, the O₂-ashing process of the subsequent process may be skipped. In other words, among the subsequent process, the O₂-ashing process may be omitted. The O₂-ashing process may be a process to remove foreign materials formed on a surface of the conductive layer 140b of the pixel electrode 140 after the conductive layer 140b of the pixel electrode 140 is formed. Referring to FIG. 6, when the O₂-ashing process is not performed, it may be seen that a current density of the pixel electrode 140 of the display device 1 increases at the same voltage, compared with a case in which the O₂-ashing process is performed. In other words, when the O₂-ashing process is skipped, as compared with a case in which the O₂-ashing process is performed, the hole injection characteristics of the pixel electrode 140 is improved so that the flow of current in the pixel electrode 140 may be improved.

By skipping the O₂-ashing process in the processes of the display device 1, a thickness t3 of the oxide layer 140c of the pixel electrode 140 may be adjusted, and thus, a ratio of the oxide layer 140c of the pixel electrode 140 and the conductive layer 140b of the pixel electrode 140 may be adjusted. The thickness t3 of the oxide layer 140c of the pixel electrode 140 may be less than or equal to about 10 Å. The ratio of the thickness t2 of the conductive layer 140b of the pixel electrode 140 and the thickness t3 of the oxide layer 140c of the pixel electrode 140 may be about 1.5:1 to about 2.33:1. When the thickness t3 of the oxide layer 140c of the pixel electrode 140 is less than about 10 Å, or when the ratio of the thickness t2 of the conductive layer 140b of the pixel electrode 140 and the thickness t3 of the oxide layer 140c of the pixel electrode 140 is about 1.5:1 to about 2.33:1, the conductive layer 140b of the pixel electrode 140 includes TIN, and thus, even when at least a portion of TiN is oxidized, or even when crystal defects are generated in TiN by the subsequent process, the hole injection characteristics of the pixel electrode 140 are improved so that the flow of current in the pixel electrode 140 may be improved.

When the thickness t3 of the oxide layer 140c exceeds about 10 Å, or when the ratio of the thickness t2 of the conductive layer 140b of the pixel electrode 140 and the thickness t3 of the oxide layer 140c of the pixel electrode 140 exceeds about 2.33:1, in other words, when the thickness t2 of the conductive layer 140b of the pixel electrode 140 exceeds about 2.33 times of the thickness t3 of the oxide layer 140c of the pixel electrode 140, due to the thickness t3 of the oxide layer 140c of the pixel electrode 140, the hole injection characteristics of the pixel electrode 140 are reduced so that the flow of current in the pixel electrode 140 is deteriorated. Thus, the luminance and the like of the display device 1 may be negatively affected. Even when the O₂-ashing process is skipped, at least portion of TiN included in the pixel electrode 140 may be oxidized by the subsequent process. The ratio of the thickness t2 of the conductive layer 140b of the pixel electrode 140 and the thickness t3 of the oxide layer 140c of the pixel electrode 140 might not be less than about 1.5:1. In other words, the thickness t2 of the conductive layer 140b of the pixel electrode 140 might not be less than about 1.5 times of the thickness t3 of the oxide layer 140c of the pixel electrode 140.

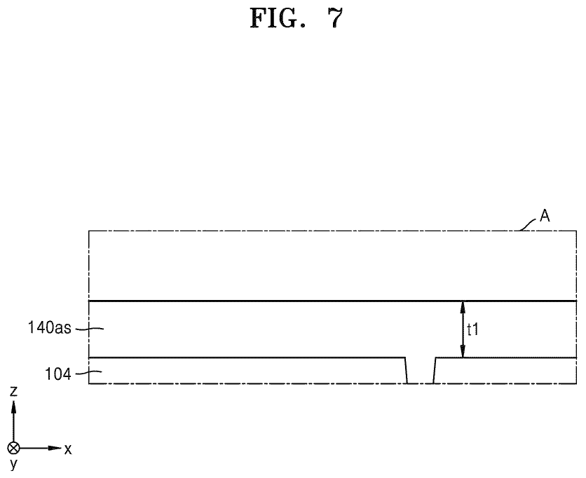

FIGS. 7 to 12 are schematic cross-sectional views of a method of manufacturing a pixel electrode of a display device, according to one or more embodiments.

Referring to FIG. 7, a reflective-layer-forming material 140as of the pixel electrode 140 may be formed on the substrate 100. In detail, the reflective-layer-forming material 140as of the pixel electrode 140 may be formed on the organic insulating layer 104. In one or more embodiments, before the reflective-layer-forming material 140as of the pixel electrode 140 is formed on the substrate 100, the pixel circuit layer PCL of FIG. 1 may be formed on the substrate 100. The pixel circuit layer PCL may be electrically connected to the reflective layer 140a of the pixel electrode 140. The reflective-layer-forming material 140as of the pixel electrode 140 may be formed on the pixel circuit layer PCL. The reflective-layer-forming material 140as of the pixel electrode 140 may include an Al—Cu alloy. In the Al—Cu alloy, the atomic ratio of Cu may have a range of greater than or equal to about 0.01 at % and less than or equal to about 0.1 at %. A thickness t1 of the reflective-layer-forming material 140as may be greater than or equal to about 800 Å and less than or equal to about 1200 Å.

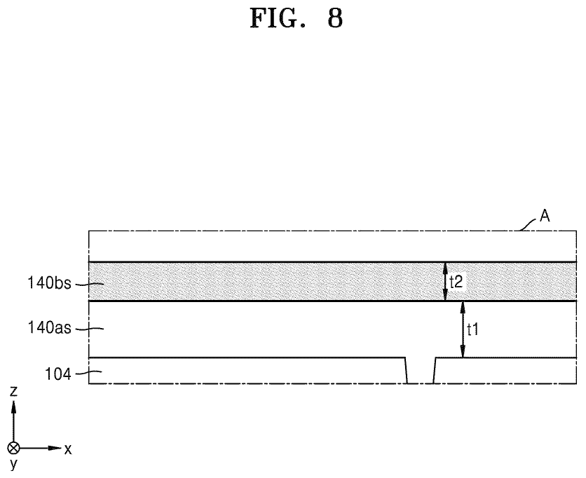

Referring to FIG. 8, a conductive-layer-forming material 140bs of the pixel electrode 140 may be formed on the reflective-layer-forming material 140as. The conductive-layer-forming material 140bs may include TiN. As described above, for the display device 1 according to one or more embodiments, the semiconductor substrate is used, and in the semiconductor process, there is a limitation in selecting the material of the pixel electrode 140, and thus, the conductive-layer-forming material 140bs of the pixel electrode 140 may include TiN. A thickness t2 of the conductive-layer-forming material 140bs of the pixel electrode 140 may be greater than or equal to about 20 Å and less than or equal to about 100 Å.

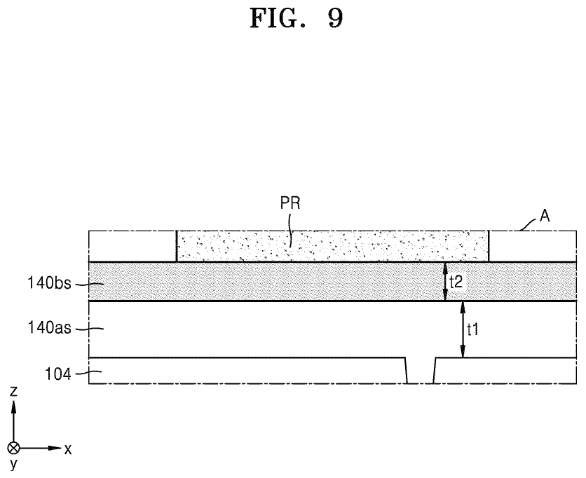

Referring to FIG. 9, photoresist PR may be formed on at least a portion of the conductive-layer-forming material 140bs of the pixel electrode 140. Portions of the reflective-layer-forming material 140as and the conductive-layer-forming material 140bs, which are arranged below a region where the photoresist PR is arranged, may avoid being etched in an etching process. Reversely, other portions of the reflective-layer-forming material 140as and the conductive-layer-forming material 140bs, which are at regions corresponding to regions on which the photoresist PR is not arranged, may be etched in the etching process.

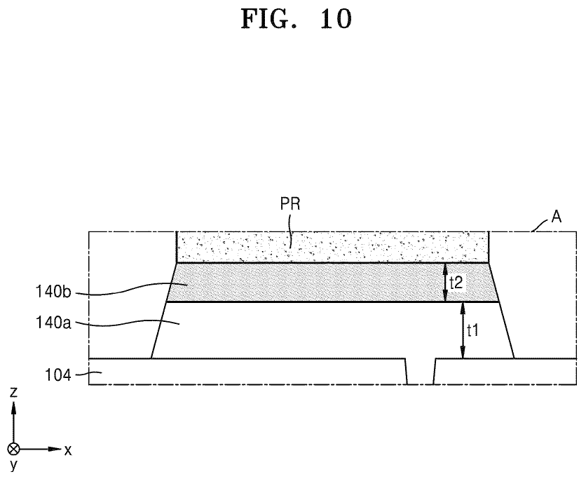

Referring to FIG. 10, at least portions of the reflective-layer-forming material 140as and the conductive-layer-forming material 140bs of the pixel electrode 140 are etched so that the reflective layer 140a of the pixel electrode 140 and the conductive layer 140b may be formed respectively. The at least portions of the reflective-layer-forming material 140as and the conductive-layer-forming material 140bs of the pixel electrode 140, on which the photoresist PR is not arranged, may be etched (e.g., dry etched) and removed. The reflective-layer-forming material 140as and the conductive-layer-forming material 140bs of the pixel electrode 140, on which the photoresist PR is arranged, may not be etched in the etching process, and may remain thereafter.

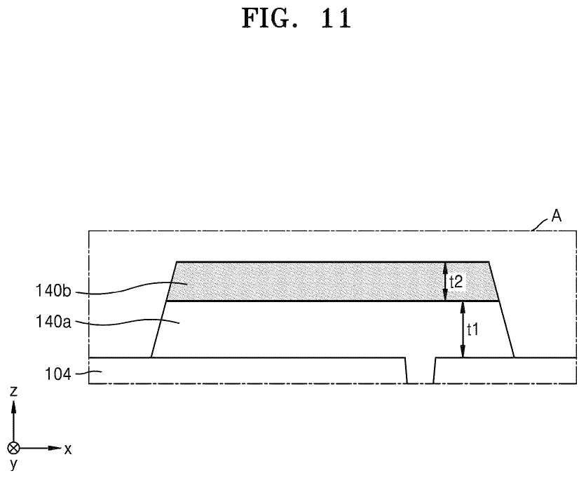

Referring to FIG. 11, the photoresist PR may be removed. The thickness t1 of the reflective layer 140a of the pixel electrode 140 may be greater than or equal to about 800 Å and less than or equal to about 1200 Å. When the thickness t1 of the reflective layer 140a of the pixel electrode 140 is less than 800 Å, the reflectivity of the display device 1 may not be secured. When the thickness t1 of the reflective layer 140a of the pixel electrode 140 exceeds about 1200 Å, the resistance of the pixel electrode 140 of the display device 1 increases so that the flow of current in the pixel electrode 140 may be deteriorated, and thus, the luminance and the like of the display device 1 may be negatively affected. The thickness t2 of the conductive layer 140b of the pixel electrode 140 may be greater than or equal to about 20 Å and less than or equal to about 100 Å. When the thickness t2 of the conductive layer 140b of the pixel electrode 140 is less than about 20 Å, the composition ratio of elements of TiN included in the conductive layer 140b may become non-uniform, and as the work function is changed, the hole injection characteristics of the pixel electrode 140 may be deteriorated. When the thickness t2 of the conductive layer 140b of the pixel electrode 140 exceeds about 100 Å, the reflectivity of the display device 1 may be deteriorated.

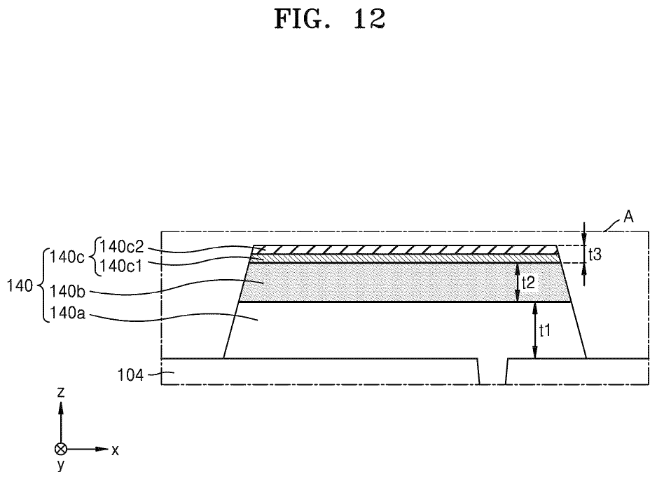

Referring to FIG. 12, as at least a portion of the TIN included in the conductive layer 140b is oxidized, the oxide layer 140c may be formed on the conductive layer 140b of the pixel electrode 140. The oxide layer 140c of the pixel electrode 140 may include TiON or TiOₓ. The oxide layer 140c of the pixel electrode 140 may include the first oxide layer 140c1 and the second oxide layer 140c2. The second oxide layer 140c2 may be located on the first oxide layer 140c1. The first oxide layer 140c1 may include TION. The second oxide layer 140c2 may include TiOₓ. Due to the process of the semiconductor substrate, TiN included in the pixel electrode 140 is oxidized so that the oxide layer 140c is formed to be relatively thick, the hole injection characteristics of the pixel electrode 140 is deteriorated, the flow of current in the pixel electrode 140 is deteriorated, and thus, the luminance and the like of the display device 1 may be negatively affected. When the O₂-ashing process that is a process of removing the foreign material on the surface of the conductive layer 140b of the processes of the display device 1 is not performed, the thickness t3 of the oxide layer 140c of the pixel electrode 140 may be adjusted. When the O₂-ashing process is skipped among the processes of the display device 1, the thickness t3 of the oxide layer 140c of the pixel electrode 140 may be less than or equal to about 10 Å. The ratio of the thickness t2 of the conductive layer 140b of the pixel electrode 140 and the thickness t3 of the oxide layer 140c of the pixel electrode 140 may be about 1.5:1 to about 2.33:1. When the thickness t3 of the oxide layer 140c of the pixel electrode 140 is adjusted by skipping the O₂-ashing process, the hole injection characteristics of the pixel electrode 140 is improved so that the flow of current in the pixel electrode 140 may be improved, and thus, the luminance and the like of the display device 1 may be positively affected.

According to the related art, to secure the hole injection characteristics of a pixel electrode of a display device, ITO is used as the material of the pixel electrode. For the display device 1 having the size of a pixel is several micrometers according to one or more embodiments, to realize a high resolution, a semiconductor substrate may be used as the substrate 100. When the semiconductor substrate is used, in the semiconductor process, TiN may be used instead of ITO, ITO being the existing material of pixel electrode of a display device in the related art.

When the pixel electrode 140 includes TiN, through the subsequent process, for example, by the O₂-ashing process, the oxide layer including TION or TiOₓ may be formed to be thick, the hole injection characteristics of the pixel electrode 140 is deteriorated, the flow of current in the pixel electrode is deteriorated, and thus, the luminance and the like of the display device 1 may be negatively affected.

By adjusting the thickness t3 of the oxide layer 140c of the pixel electrode 140 by skipping the O₂-ashing process in the processes of the display device 1, the thickness t3 of the oxide layer 140c is less than or equal to about 10 Å, or the ratio of the thickness t2 of the conductive layer 140b of the pixel electrode 140 and the thickness t3 of the oxide layer 140c of the pixel electrode 140 may be about 1.5:1 to about 2.33:1. When the thickness t3 of the oxide layer 140c of the pixel electrode 140 is adjusted by skipping the O₂-ashing process, the hole injection characteristics of the pixel electrode 140 is improved so that the flow of current in the pixel electrode 140 may be improved, and thus, the luminance and the like of the display device 1 may be positively affected.

According to the one or more embodiments described above, a display device with improved reliability, and a method of manufacturing the display device, may be implemented. Of course, the scope of the disclosure is not limited by the above aspects.

It should be understood that embodiments described herein should be considered in a descriptive sense only and not for purposes of limitation. Descriptions of aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, with functional equivalents thereof to be included therein.

What is claimed is:

1. A display device comprising:
a substrate;
a pixel circuit layer above the substrate, and comprising at least one thin film transistor; and
a pixel electrode above the pixel circuit layer, and electrically connected to the thin film transistor,
wherein the pixel electrode comprises a reflective layer, a conductive layer above the reflective layer, and an oxide layer above the conductive layer, and
wherein a ratio of a thickness of the conductive layer and a thickness of the oxide layer is about 1.5:1 to about 2.33:1.

2. The display device of claim 1, wherein the thickness of the conductive layer is greater than or equal to about 20 Å and less than or equal to about 100 Å.

3. The display device of claim 1, wherein the thickness of the oxide layer is less than or equal to about 10 Å.

4. The display device of claim 1, wherein a thickness of the reflective layer is greater than or equal to about 800 Å and less than or equal to about 1,200 Å.

5. The display device of claim 1, wherein the conductive layer comprises titanium nitride (TiN).

6. The display device of claim 1, wherein the oxide layer comprises titanium oxynitride (TiON) or titanium oxide (TiOₓ).

7. The display device of claim 1, wherein the oxide layer comprises:
a first oxide layer comprising titanium oxynitride (TION); and
a second oxide layer above the first oxide layer, and comprising titanium oxide (TiOₓ).

8. The display device of claim 1, wherein the reflective layer comprises an aluminum-copper alloy (Al—Cu alloy).

9. The display device of claim 8, wherein an atomic ratio of Cu in the aluminum-copper alloy (Al—Cu alloy) is greater than or equal to about 0.01 at % and less than or equal to about 0.1 at %.

10. The display device of claim 1, wherein the substrate comprises a semiconductor substrate.

11. A method of manufacturing a display device, the method comprising:
forming, on a substrate, a pixel circuit layer comprising at least one thin film transistor;
forming, on the pixel circuit layer, a reflective layer of a pixel electrode electrically connected to the pixel circuit layer;
forming a conductive layer of the pixel electrode on the reflective layer of the pixel electrode; and
forming an oxide layer on the conductive layer of the pixel electrode, by oxidizing at least a portion of a material comprised in the conductive layer,
wherein a ratio of a thickness of the conductive layer and a thickness of the oxide layer is about 1.5:1 to about 2.33:1.

12. The method of claim 11, wherein the forming the reflective layer and forming the conductive layer comprises:
forming a reflective-layer-forming material on the pixel circuit layer;
forming a conductive-layer-forming material on the reflective-layer-forming material;
forming photoresist on at least a portion of the conductive-layer-forming material;
forming the reflective layer and the conductive layer by etching at least portions of the reflective-layer-forming material and the conductive-layer-forming material on which the photoresist is not arranged; and
removing the photoresist.

13. The method of claim 11, further comprising skipping ashing a surface of the conductive layer with oxygen (O₂) after the forming the conductive layer.

14. The method of claim 11, wherein the thickness of the conductive layer is greater than or equal to about 20 Å and less than or equal to about 100 Å.

15. The method of claim 11, wherein the thickness of the oxide layer is less than or equal to about 10 Å.

16. The method of claim 11, wherein a thickness of the reflective layer is greater than or equal to about 800 Å and less than or equal to about 1,200 Å.

17. The method of claim 11, wherein the conductive layer comprises titanium nitride (TiN), and
wherein the oxide layer comprises titanium oxynitride (TION) or titanium oxide (TiOₓ).

18. The method of claim 11, wherein the oxide layer comprises:
a first oxide layer comprising titanium oxynitride (TION); and
a second oxide layer above the first oxide layer, and comprising titanium oxide (TiOₓ).

19. The method of claim 11, wherein the reflective layer comprises an aluminum-copper alloy (Al—Cu alloy), and
wherein, in the aluminum-copper alloy (Al—Cu alloy), an atomic ratio of Cu is greater than or equal to about 0.01 at % and less than or equal to about 0.1 at %.

20. The method of claim 11, wherein the substrate comprises a semiconductor substrate.
